(19) United States
(12) Patent Application Publication
(10) Pub. No.: US 2003/0137810 A1
(43) Pub. Date: Jul. 24, 2003

(54) Housing of power supply apparatus for securing power cord thereon

(76) Inventor: Chen Chun Chen, Taoyuan (TW)

Correspondence Address: STRADLING YOCCA CARLSON & RAUTH,, IP Department, P.O. Box 7680, 660 Newport Center Drive, Suite 1600, Newport Beach, CA, 92660-6441, US

(21) Appl. No.: 10/057,668

(22) Filed: Jan. 24, 2002

(51) Int. Cl. H05K 5/00; H05K 5/04; H05K 5/06

(52) U.S. Cl. 361/752

(57) ABSTRACT

A power supply apparatus is provide. The power supply apparatus includes a housing, a circuit board for converting the AC power supply into a DC power supply, a power cord for transferring the DC power supply to an electrical appliance. The housing includes a first side extending therefrom a first end of the power cord, a winding portion essentially perpendicular to the first side, and a first protrusion and a second protrusion extending from a surface of the winding portion, wherein a channel is defined between the first protrusion and the second protrusion. In such way, the power cord is guided by the channel and wound around the winding portion for storage.

### FIELD OF THE INVENTION

The present invention relates to a power supply apparatus, and more particularly to a power supply apparatus for securing power cord on its housing.

### BACKGROUND OF THE INVENTION

An electronic appliance, such as a printer, a radio, a modem and a notebook, is generally equipped with an adapter for rectifying and converting the commercially available AC power supply into direct current (DC) power supply, so as to supply the required power to operate the electronic appliance.

FIG. 1 is a view illustrating an adapter of the prior art. The adapter includes a housing 11, wherein one side 111 of the housing 11 has an AC inlet 12 matching with a corresponding connector 161. The connector 161 is provided on one end of a power cable 162, while the other end of the power cable 162 is provided with a plug 163. The power adapter of FIG. 1 receives commercially available AC power supply by connecting the plug 163 to a wall socket (not shown). Another side 112 of the adapter extends a power cord 14 for transferring the DC power supply to an electronic appliance.

Since the power cord 14 has a length of from about 1 to 10 meters, a special consideration should be given to secure the power cord 14. A strap 15 is widely used to secure a bundled power cord 14 for storage. When the adapter is to be employed, the strap 15 has to be unfastened in advance and the power cord 14 can be stretched out to be connected with an electronic appliance.

However, the above-mentioned power cord securing device still has some disadvantages in practice:

1. the bundling strap 15 is readily lost, because the strap 15 is isolated from the adapter housing 11; and

2. the bundled power cord 14 is suspended over the housing 11, which results in an inferior appearance and occupies a lot of space.

### SUMMARY OF THE INVENTION

In accordance with an aspect of the present invention, there is provided a power supply apparatus. The power supply apparatus includes a housing, a circuit board for converting the AC power supply into a DC power supply, a power cord for transferring the DC power supply to an electrical appliance. The housing includes a first side extending therefrom a first end of the power cord, a winding portion essentially perpendicular to the first side, and a first protrusion and a second protrusion extending from a surface of the winding portion, wherein a channel is defined between the first protrusion and the second protrusion. In such way, the power cord is guided by the channel and wound around the winding portion for storage.

Preferably, the power supply apparatus further includes a locking element disposed in the vicinity of a second end of the power cord.

Preferably, the locking element comprises a clipper for clamping the power cord wound around the winding portion.

Preferably, the housing further comprises a plug receptacle in a second side opposite to the first side for being connected with a removable AC inlet.

Preferably, the first side has an aperture for passing the first end of the power cord such that the power cord is electrically connected with the circuit board.

Preferably, the level of the channel is essentially the same as that of the aperture.

Preferably, the width of the channel is the same as the outer diameter of the power cord.

Preferably, the first protrusion and the second protrusion are integrally formed with the housing.

In accordance with another aspect of the present invention, there is provided a structure of an adapter. The structure of the adapter includes a circuit board, a power cord, an upper housing and a lower housing. The circuit board is used for converting the AC power supply into a DC power supply. The power cord has a first end electrically connected with the circuit board and a second end for being coupled with an electrical appliance. The upper housing having a first protrusion. The lower housing having a second protrusion. When the upper housing and the lower housing are jointed together, a first side, a winding portion and a channel are defined. The channel is arranged between the first protrusion and the second protrusion, the first side has an aperture for passing the first end of the power cord, and the winding portion is essentially perpendicular to the first side. In such way, the power cord is guided by the channel and wound around the winding portion for storage.

Preferably, the first protrusion and the second protrusion are integrally formed with the upper housing and the lower housing, respectively.

In accordance with another aspect of the present invention, there is provided an adapter. The adapter includes a circuit board for converting the AC power supply into a DC power supply, a power cord having a first end electrically connected with the circuit board and a second end for being coupled with an electrical appliance, an upper housing having a first protrusion integrally formed therewith, and a lower housing having a second protrusion integrally formed therewith. When the upper housing and the lower housing are jointed together, a first side, a winding portion and a channel are defined. The channel is arranged between the first protrusion and the second protrusion, the first side has an aperture for passing the first end of the power cord, and the winding portion is essentially perpendicular to the first side. In such way, the power cord is guided by the channel and wound around the winding portion for storage.

The above objects and advantages of the present invention will become more readily apparent to those ordinarily skilled in the art after reviewing the following detailed description and accompanying drawings, in which:

### BRIEF DESCRIPTION OF THE DRAWINGS

FIG. 1 is a perspective view showing a power cord securing device for an adapter according to the prior art;

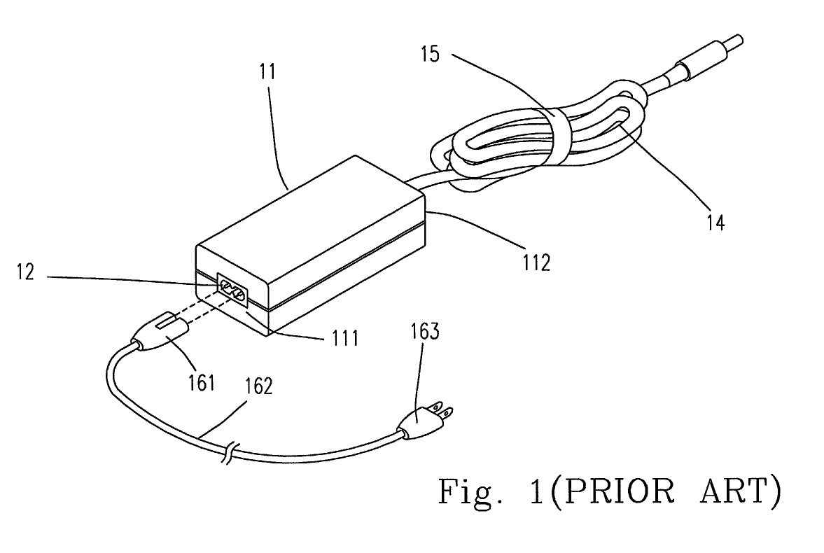

FIG. 2 is a perspective view showing the housing of an adapter according to a preferred embodiment of the present invention;

FIG. 3 is a schematic diagram illustrating the power cord is secured on the housing of the adapter in FIG. 2; and

FIG. 4 is schematic diagram illustrating a removable AC inlet is coupled with the plug receptacle.

### DETAILED DESCRIPTION OF THE PREFERRED EMBODIMENT

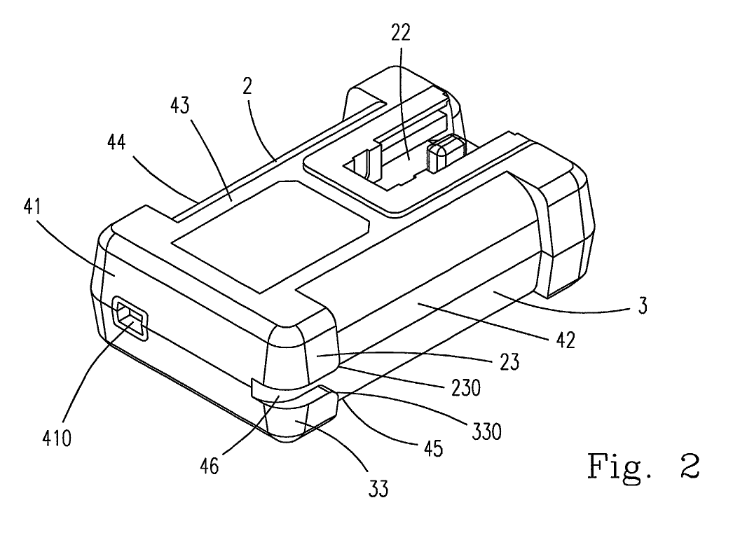

Please refer to FIG. 2. The main body of the adapter according to the present invention is shaped almost like a rectangular box, and includes an upper housing 2 and a lower housing 3. A circuit board (not shown) is disposed within the space between the upper housing 2 and the lower housing 3 for converting the AC power supply into a DC power supply. The operation and principle of the circuit board are well known in the art and need not be further described in details herein.

When the upper housing 2 and the lower housing are jointed together, an aperture 410 and a channel 46 are defined. The main body of the adapter includes a first side 41 and a winding portion, in which the winding portion essentially consists of four winding surfaces 42 to 45 perpendicular to the first side 410. The adapter further has a plug receptacle 22 on the second side opposite to the first side 41. The plug receptacle 22 is employed for accommodating a removable AC inlet (not shown) so as to accept an AC power supply, which is also well known in the art.

On the winding surface 42, the upper housing 2 and the lower housing 3 have a first protrusion 23 and a second protrusion 33, respectively. A channel 46 is formed and defined between the first protrusion 23 and the second protrusion 33. Because the first protrusion 23 and the second protrusion 33 are integrally formed with the upper housing 2 and the lower housing 3, the housing is easily fabricated.

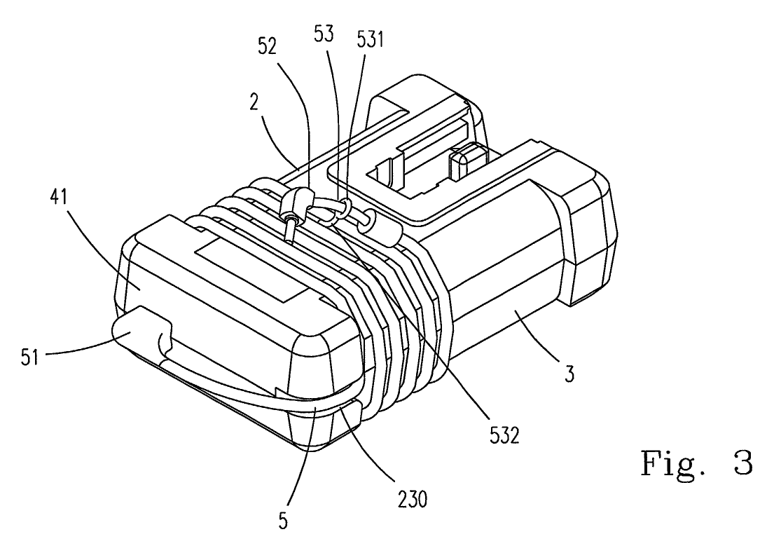

Please refer to FIG. 3. The power cord 5 is secured on the winding surfaces 42 to 45. The power cord 5 has a first end 51 electrically connected to the circuit board via the aperture 410. The remaining power cord 5 is subsequently guided by the channel 46 and wound around the winding surfaces 42 to 45. In this embodiment, the level of the channel 46 is essentially the same as that of the aperture 410, and the width of the channel 46 is preferably the same as the outer diameter of the power cord. Therefore, the power cord 5 is preliminarily fixed and guided by the channel 46. Preferably, the edges 230, 330 of the first protrusion 23 and the second protrusion 33 is cambered at an appropriate radian so as to guide the power cord 5 smoothly.

Furthermore, a locking element 53 is provided in the vicinity of a second end (i.e. near the DC connector 52) of the power cord 53 to clamp the wound power cord 5 so as to fix the power cord 5. The locking element 53 is preferably made of plastic and includes a ring 531 and a clipper 532, wherein the ring 531 is jointed on the power cord 5.

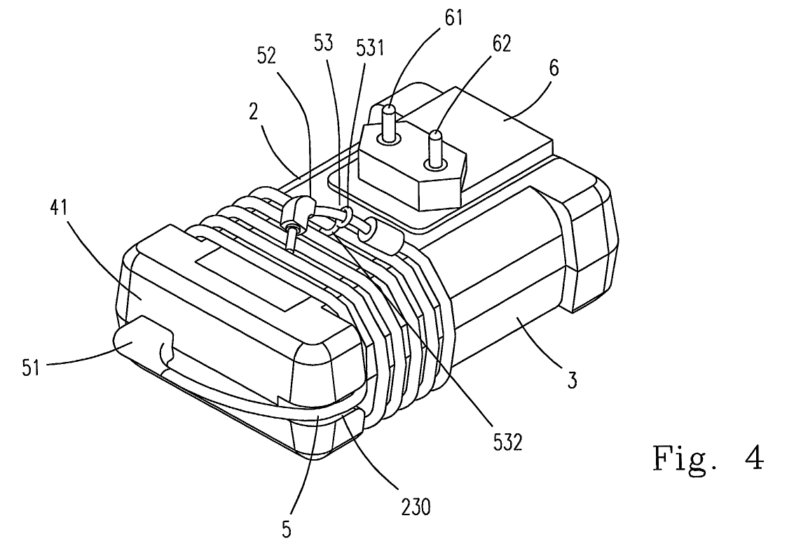

Referring to FIG. 4, a removable AC inlet 6 is coupled with the plug receptacle 22. The removable AC inlet 6 includes two conducting terminals 61 and 62 to be inserted into a corresponding wall socket. Certainly, the number and the shape of the conducting terminals can be chosen in accordance with the particular technical requirements.

As will be apparent from the above description, the housing of the present invention has the following advantages:

1. since the first protrusion 23 and the second protrusion 33 are integrally formed with the upper housing 2 and the lower housing 3, the housing is easily fabricated;

2. the channel 46 is formed when the upper housing 2 and the lower housing 3 are jointed together power cord 5, which is user-friendly;

3. the power cord 5 is preliminarily fixed and guided by the channel 46, and finally retained by the locking element 5, such that the power cord is effectively secured for storage; and

4. since the power cord is secured on the housing, the power cord will be no longer suspended over the housing and the problem of losing bundling strap 15 will not exist.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A power supply apparatus comprising a housing, a circuit board for converting said AC power supply into a DC power supply, a power cord for transferring said DC power supply to an electrical appliance, characterized in that said housing comprising:
a first side extending therefrom a first end of said power cord;
a winding portion essentially perpendicular to said first side; and
a first protrusion and a second protrusion extending from a surface of said winding portion, wherein a channel is defined between said first protrusion and said second protrusion;
wherein said power cord is guided by said channel and wound around said winding portion for storage.

2. The power supply apparatus according to claim 1 further comprising a locking element disposed in the vicinity of a second end of said power cord.

3. The power supply apparatus according to claim 2 wherein said locking element comprises a clipper for clamping said power cord wound around said winding portion.

4. The power supply apparatus according to claim 1 wherein said housing further comprises a plug receptacle in a second side opposite to said first side for being connected with a removable AC inlet.

5. The power supply apparatus according to claim 1 wherein said first side has an aperture for passing said first end of said power cord such that said power cord is electrically connected with said circuit board.

6. The power supply apparatus according to claim 5 wherein the level of said channel is essentially the same as that of said aperture.

7. The power supply apparatus according to claim 1 wherein the width of said channel is the same as the outer diameter of said power cord.

8. The power supply apparatus according to claim 1 wherein said first protrusion and said second protrusion are integrally formed with said housing.

9. A structure of an adapter comprising:
a circuit board for converting said AC power supply into a DC power supply;
a power cord having a first end electrically connected with said circuit board and a second end for being coupled with an electrical appliance;
an upper housing having a first protrusion; and
a lower housing having a second protrusion, wherein when said upper housing and said lower housing are jointed together, a first side, a winding portion and a channel are defined, said channel being between said first protrusion and said second protrusion, said first side having an aperture for passing said first end of said power cord, and said winding portion being essentially perpendicular to said first side,
wherein said power cord is guided by said channel and wound around said winding portion for storage.

10. The structure according to claim 9 further comprising a locking element disposed in the vicinity of said second end of said power cord.

11. The structure according to claim 10 wherein said locking element comprises a clipper for clamping said wound power cord wound around said winding portion.

12. The structure according to claim 9 wherein the level of said channel is essentially the same as that of said aperture.

13. The structure according to claim 9 wherein the width of said channel is the same as the outer diameter of said power cord.

14. The structure according to claim 9 wherein said first protrusion and said second protrusion are integrally formed with said upper housing and said lower housing, respectively.

15. An adapter comprising:
a circuit board for converting said AC power supply into a DC power supply;
a power cord having a first end electrically connected with said circuit board and a second end for being coupled with an electrical appliance;
an upper housing having a first protrusion integrally formed therewith; and
a lower housing having a second protrusion integrally formed therewith, wherein when said upper housing and said lower housing are jointed together, a first side, a winding portion and a channel are defined, said channel being between said first protrusion and said second protrusion, said first side having an aperture for passing said first end of said power cord, and said winding portion being essentially perpendicular to said first side,
wherein said power cord is guided by said channel and wound around said winding portion for storage.

16. The adapter according to claim 15 further comprising a locking element disposed in the vicinity of said second end of said power cord.

17. The adapter according to claim 16 wherein said locking element comprises a clipper for clamping said wound power cord wound around said winding portion.

18. The adapter according to claim 15 wherein the level of said channel is essentially the same as that of said aperture.

19. The adapter according to claim 15 wherein the width of said channel is the same as the outer diameter of said power cord.
